(19) United States
(12) Patent Application Publication
(10) Pub. No.: US 2015/0303204 A1
(43) Pub. Date: Oct. 22, 2015

(54) NONVOLATILE MEMORY DEVICES HAVING CHARGE TRAPPING LAYERS AND METHODS OF FABRICATING THE SAME

(71) Applicant: SK hynix Inc., Gyeonggi-do (KR)

(72) Inventor: Young Joon KWON, Chungcheongbuk-do (KR)

(21) Appl. No.: 14/341,567

(22) Filed: Jul. 25, 2014

(30) Foreign Application Priority Data
Apr. 18, 2014 (KR) 10-2014-0046994

(51) Int. Cl. H01L 27/115; H01L 21/28; H01L 29/66; H01L 29/10; H01L 29/51; H01L 29/792

(52) U.S. Cl. CPC H01L 27/1157; H01L 29/513; H01L 29/518; H01L 29/792; H01L 27/11565; H01L 29/66833; H01L 29/1095; H01L 21/28282

(57) ABSTRACT

A nonvolatile memory device includes a substrate having a first charge trap region, a second charge trap region, and a selection region between the first and second charge trap regions. A well region is disposed in the substrate. A source region and a drain region are disposed in the well region. A gate structure is disposed on a channel region between the source region and the drain region. The gate structure includes: a first tunneling layer, a first charge trap layer, a first blocking layer and a first conductive layer stacked in the first charge trap region; a second tunneling layer, a second charge trap layer, a second blocking layer and a second conductive layer stacked in the second charge trap region; and a first insulation layer, a second insulation layer, a third insulation layer and a third conductive layer stacked in the selection region.

### CROSS-REFERENCE TO RELATED APPLICATION

The present application claims priority under 35 U.S.C. 119(a) to Korean Application No. 10-2014-0046994, filed on Apr. 18, 2014, in the Korean intellectual property Office, which is incorporated herein by reference in its entirety.

### BACKGROUND

1. Technical Field

Various embodiments of the present disclosure relate to nonvolatile memory devices and methods of fabricating the same and, more particularly, to nonvolatile memory devices having charge trapping layers and methods of fabricating the same.

2. Related Art

Semiconductor memory devices are typically categorized as volatile memory devices or nonvolatile memory devices. Volatile memory devices lose their stored data when their power supplies are interrupted but have relatively high operating speeds (e.g., they read out data stored in memory cells or write data into the memory cells relatively quickly). In contrast, nonvolatile memory devices retain their stored data when their power supplies are interrupted but tend to operate at lower speeds. Therefore, nonvolatile memory devices are used in electronic systems that need to retain data without having a constant power source. Nonvolatile memory devices include mask read only memory (MROM) devices, programmable read only memory (PROM) devices, erasable programmable read only memory (EPROM) devices, electrically erasable programmable read only memory (EEPROM) devices, flash memory devices, etc.

In general, the MROM devices, the PROM devices, and the EPROM devices need additional equipment (e.g., a UV irradiator) to erase their stored data. Thus, it may be inconvenient to use MROM devices, PROM devices, and EPROM devices in many applications. In contrast, EEPROM devices and flash memory devices allow data to be electrically erased and written without additional equipment. Accordingly, EEPROM devices and flash memory devices may be applied in various areas, for example, systems for program executions or auxiliary memory devices necessitating frequent data renewals. In particular, flash memory devices may be simultaneously erased in units (e.g., in pages) and are capable of achieving higher integration densities than EEPROM devices. Therefore, flash memory devices are often used in large capacity auxiliary memory devices.

The amount of data that nonvolatile memory devices are capable of storing in each memory cell depends on the number of bits that are stored in each memory cell. A memory cell in which a single bit of data is stored is referred to as a single bit cell or a single level cell (SLC). In contrast, a memory cell in which multi-bit data (e.g., data including two bit or more) is stored is referred to as a multi-bit cell, a multi-level cell (MLC) or a multi-state cell. As semiconductor memory devices become more highly integrated, nonvolatile memory devices employing MLCs have garnered the attention of the semiconductor industry.

Flash memory and EEPROM devices generally have a stacked gate structure including a floating gate and a control gate electrode, which are vertically stacked. However, if the distance between the memory cells is reduced too much, threshold voltages of the memory cells may become unstable due to interference effects or coupling capacitances between the memory cells. Therefore, a lot of research and development goes into perfecting how memory devices can more effectively store data using charge trapping layers.

### SUMMARY

Various embodiments are directed to nonvolatile memory devices having charge trapping layers and methods of fabricating the same.

According to one embodiment, a nonvolatile memory device includes a substrate having a first charge trap region, a second charge trap region, and a selection region between the first and second charge trap regions, wherein the first charge trap region, the selection region and the second charge trap region are arrayed in one direction, a well region having a first conductivity type and disposed in the substrate, wherein a surface of the well region is exposed, a source region and a drain region is disposed in the well region to be separated from each other by a channel region, wherein the source region and the drain region have a second conductivity type different from the first conductivity type, and a gate structure disposed on the channel region, where the gate structure includes a first tunneling layer, a first charge trap layer, a first blocking layer and a first conductive layer stacked in the first charge trap region; a second tunneling layer, a second charge trap layer, a second blocking layer and a second conductive layer stacked in the second charge trap region; and a first insulation layer, a second insulation layer, a third insulation layer and a third conductive layer stacked in the selection region.

According to another embodiment, a method of fabricating a nonvolatile memory device includes forming a well region in a substrate, wherein a surface of the well region is exposed, forming a first tunneling material on the well region, removing portions of the first tunneling material to form first tunneling layers exposing portions of the well region, sequentially forming a second tunneling layer, a charge trap layer and an insulation layer on the first tunneling layers and exposed portions of the well region, forming a conductive layer on the insulation layer, patterning the conductive layer, the insulation layer, the charge trap layer and the second tunneling layer to form gate structures exposing portions of the well region, and forming source/drain regions in exposed portions of the well region.

According to another embodiment, a nonvolatile memory device includes a substrate having a first charge trap region, a selection region, and a second charge trap region arrayed in one direction, a Insulating layer formed on the substrate in the selection region, a tunneling layer, a charge trap layer, and an blocking layer stacked on the Insulating layer in the selection region and on the substrate in the first and second charge trap regions, and a conductive layer formed on the blocking layer, wherein the tunneling layer, the charge trap layer, and the blocking layer have a level difference between the first charge trap region and the selection region and between the selection region and the second charge trap region

### BRIEF DESCRIPTION OF THE DRAWINGS

Embodiments of the present disclosure will become more apparent in view of the attached drawings and accompanying detailed description, in which:

FIG. 1 is a layout diagram Illustrating a unit cell of a nonvolatile memory device according to an embodiment;

FIG. 2 is a cross-sectional view taken along a line I-I′ of FIG. 1;

FIG. 3 is an equivalent circuit diagram corresponding to the unit cell shown in FIG. 1;

FIG. 4 is a table illustrating bias conditions for operations of the unit cell shown in FIG. 3;

FIG. 5 is a layout diagram illustrating a cell array employing the unit cell shown in FIG. 1;

FIG. 6 is an equivalent circuit diagram corresponding to the cell array shown in FIG. 5;

FIG. 7 is a table illustrating bias conditions for operations of the cell array shown in FIG. 6; and

FIGS. 8 to 13 are cross-sectional views illustrating a method of fabricating a nonvolatile memory device according to an embodiment.

### DETAILED DESCRIPTION OF THE EMBODIMENTS

Various embodiments will be described below in more detail with reference to the accompanying drawings. The present invention may, however, be embodied in different forms and should not be construed as limited to the embodiments set forth herein. Rather, these embodiments are provided so that this disclosure will be thorough and complete and will fully convey the scope of the present invention to those skilled in the art. The drawings are not necessarily to scale and, in some instances, proportions may have been exaggerated in order to clearly illustrate features of the embodiments. Throughout the disclosure, like reference numerals correspond directly to the like parts in the various figures and embodiments of the present invention.

In the following embodiments, it will be understood that when an element is referred to as being located “on”, “over”, “above”, “under”, “beneath” or “below” another element, it may directly contact the other element, or at least one intervening element may be present therebetween. Accordingly, the terms such as “on”, “over”, “above”, “under”, “beneath”, “below” and the like that are used herein are for the purpose of describing particular embodiments only and are not intended to limit the scope of the present disclosure.

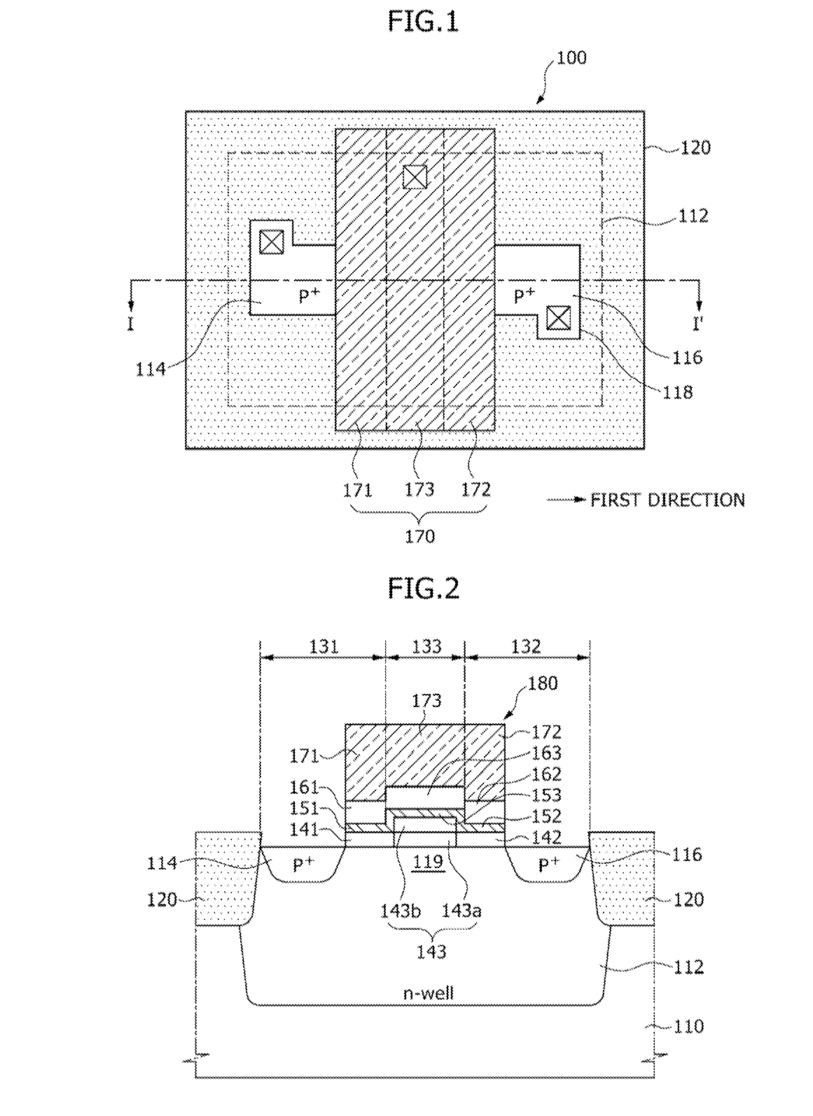

FIG. 1 is a layout diagram illustrating a unit cell of a nonvolatile memory device according to an embodiment. FIG. 2 is a cross-sectional view taken along a line I-I′ of FIG. 1. Referring to FIGS. 1 and 2, the unit cell 100 may include a substrate 110 and an N-type well region 112 disposed in the substrate 110 such that a top surface of the N-type well region 112 is exposed. The substrate 110 may have a first charge trap region 131 and a second charge trap region 132 arrayed in a first direction and a selection region 133 disposed between the first and second charge trap regions 131 and 132. A trench isolation layer 120 may be disposed in the substrate 110 to define an active region 118 extending in the first direction. A first P-type junction region 114 may be disposed in one end of the active region 118 extending in the first direction, and a second P-type junction region 116 may be disposed in the other end of the active region 118 extending in the first direction. The first P-type junction region 114 may be disposed in the first charge trap region 131, and the second P-type junction region 116 may be disposed in the second charge trap region 132. In some embodiments, the first P-type junction region 114 may correspond to a source region, and the second P-type junction region 116 may correspond to a drain region. A channel region 119 may be provided under a surface of the active region 118 between the first and second P-type junction regions 114 and 116.

A gate structure 180 may be disposed on the channel region 119. The gate structure 180 in the first charge trap region 131 may include a first tunneling layer 141, a first charge trap layer 151, a first blocking layer 161 and a first conductive layer 171 which are sequentially stacked. The first conductive layer 171 may act as a first control gate layer. The gate structure 180 in the second charge trap region 132 may include a second tunneling layer 142, a second charge trap layer 152, a second blocking layer 162 and a second conductive layer 172 which are sequentially stacked. The second conductive layer 172 may act as a second control gate layer. The gate structure 180 in the selection region 133 may include a first insulation layer 143, a second insulation layer 153, a third insulation layer 163 and a third conductive layer 173 which are sequentially stacked. The first, second and third insulation layers 143, 153 and 163 may act as a gate insulation layer, and the third conductive layer 173 may act as a gate electrode layer of a selection transistor.

The first insulation layer 143 in the selection region 133 may include a first lower insulation layer 143a and a first upper insulation layer 143b which are sequentially stacked. The first tunneling layer 141, the second tunneling layer 142 and the first upper insulation layer 143b may be the same material layer. In some embodiments, the first tunneling layer 141, the second tunneling layer 142 and the first upper insulation layer 143b may be an oxide layer. In some embodiments, the first lower insulation layer 143a may be the same insulation material layer (e.g., an oxide layer) as the first upper insulation layer 143b. Alternatively, the first lower insulation layer 143a may be an insulation material layer different from the first upper insulation layer 143b. In any case, the thickness of the first lower insulation layer 143a may be substantially equal in thickness to each of the first and second tunneling layers 141 and 142. Thus, the total thickness of the first insulation layer 143 may be greater than the thickness of each of the first and second tunneling layers 141 and 142 by the thickness of the first upper insulation layer 143b. Accordingly, there may be a level difference between the first tunneling layer 141 in the first charge trap region 131 and the first insulation layer 143 in the selection region 133, and between the second tunneling layer 142 in the second charge trap region 132 and the first insulation layer 143 in the selection region 133.

The first charge trap layer 151, the second charge trap layer 152 and the second insulation layer 153 may constitute a single material layer without any heterogeneous junctions therebetween. There may be a level difference between the first charge trap layer 151 in the first charge trap region 131 and the second insulation layer 153 in the selection region 133, and between the second charge trap layer 152 in the second charge trap region 132 and the second insulation layer 153 in the selection region 133. The level difference between the first charge trap layer 151 and the second insulation layer 153 as well as between the second charge trap layer 152 and the second insulation layer 153 may be substantially equal to the thickness of the first upper insulation layer 143b. In some embodiments, the first charge trap layer 151, the second charge trap layer 152 and the second insulation layer 153 may be the same material layer, for example, a nitride layer.

The first blocking layer 161, the second blocking layer 162 and the third insulation layer 163 may constitute a single material layer without any heterogeneous junctions therebetween. There may be a step difference between the first blocking layer 161 in the first charge trap region 131 and the third insulation layer 163 in the selection region 133, and between the second blocking layer 162 in the second charge trap region 132 and the third insulation layer 163 in the selection region 133. The level difference between the first blocking layer 161 and the third insulation layer 163 as well as between the second blocking layer 162 and the third insulation layer 163 may be substantially equal to the thickness of the first upper insulation layer 143b. In some embodiments, the first blocking layer 161, the second blocking layer 162 and the third insulation layer 163 may be the same material layer, for example, an oxide layer.

The first conductive layer 171, the second conductive layer 172 and the third conductive layer 173 may constitute a single material layer without any heterogeneous junctions therebetween. There may be a level difference between a bottom surface of the first conductive layer 171 in the first charge trap region 131 and a bottom surface of the third conductive layer 173 in the selection region 133, and between a bottom surface of the second conductive layer 172 in the second charge trap region 132 and a bottom surface of the third conductive layer 173 in the selection region 133. The level difference between the first conductive layer 171 and the third conductive layer 173 as well as between the second conductive layer 162 and the third conductive layer 173 may be substantially equal to a thickness of the first upper insulation layer 143b. In some embodiments, the first conductive layer 171, the second conductive layer 172 and the third conductive layer 173 may be the same material layer, for example, a polysilicon layer. The first conductive layer 171, the second conductive layer 172 and the third conductive layer 173 may constitute a gate conductive layer 170.

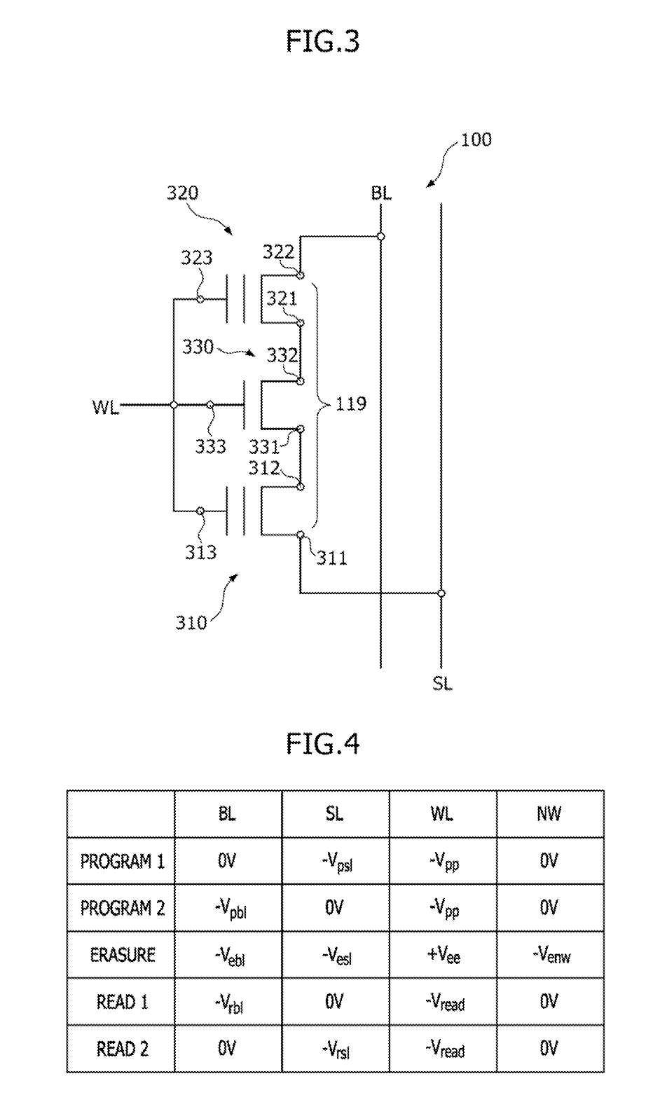

FIG. 3 is an equivalent circuit diagram corresponding to the unit cell shown in FIG. 1. Referring to FIGS. 1, 2 and 3, the unit cell 100 of the nonvolatile memory device may include a first charge trap transistor 310, a second charge trap transistor 320 and a selection transistor 330. The first charge trap transistor 310 may have a first terminal 311, a second terminal 312 and a first gate terminal 313. The second charge trap transistor 320 may have a first terminal 321, a second terminal 322 and a second gate terminal 323. The selection transistor 330 may have a first terminal 331, a second terminal 332 and a third gate terminal 333.

The first terminal 311 of the first charge trap transistor 310 may correspond to the first P-type junction region 114 shown in FIGS. 1 and 2 and may be electrically connected to a source line SL. The second terminal 312 of the first charge trap transistor 310 may be directly connected to the first terminal 331 of the selection transistor 330 without any intervening junction regions. The second terminal 332 of the selection transistor 330 may be directly connected to the first terminal 321 of the second charge trap transistor 320 without any intervening junction regions. The second terminal 322 of the second charge trap transistor 320 may correspond to the second P-type junction region 116 shown in FIGS. 1 and 2 and may be electrically connected to a bit line BL.

The first gate terminal 313 of the first charge trap transistor 310 may correspond to the first conductive layer 171 in the first charge trap region 131 of FIG. 2. The second gate terminal 323 of the second charge trap transistor 320 may correspond to the second conductive layer 172 in the second charge trap region 132 of FIG. 2. In addition, the third gate terminal 333 of the selection transistor 330 may correspond to the third conductive layer 173 in the selection region 133 of FIG. 2. As described with reference to FIGS. 1 and 2, the first conductive layer 171, the second conductive layer 172 and the third conductive layer 173 constitute a single material layer. Thus, the first gate terminal 313, the second gate terminal 323 and the third gate terminal 333 may be electrically connected to a single word line WL.

FIG. 4 is a table illustrating bias conditions for operations of the unit cell shown in FIG. 3. Referring to FIGS. 1, 2, 3 and 4, to perform a first program operation (PROGRAM 1) for selectively programming the first charge trap transistor 310 of the unit cell 100, a negative program voltage −Vpp may be applied to the word line WL and a first negative source line voltage −Vpsl may be applied to the source line SL. During the first program operation, the bit line BL and the N-type well region NW may be grounded. If a negative program voltage −Vpp is applied to the word line WL, the selection transistor 330 and the second charge trap transistor 320 may be turned on to generate channel hot holes in the N-type well region 112 adjacent to the first P-type junction region 114. These channel hot holes may be injected and trapped into the first charge trap layer 151 in the first charge trap region 131 due to an electric field created by the negative program voltage −Vpp applied to the word line WL and the first negative source line voltage −Vpsl applied to the source line SL. As a result, the absolute value of the threshold voltage of the first charge trap transistor 310 may increase such that the first charge trap transistor 310 has a programmed state.

To perform a second program operation (PROGRAM 2) for selectively programming the second charge trap transistor 320 of the unit cell 100, a negative program voltage −Vpp may be applied to the word line WL and a first negative bit line voltage −Vpbl may be applied to the bit line BL. During the second program operation, the source line SL and the N-type well region NW may be grounded. If the negative program voltage −Vpp is applied to the word line WL, the selection transistor 330 and the first charge trap transistor 310 may be turned on to generate channel hot holes in the N-type well region 112 adjacent to the second P-type junction region 116. These channel hot holes may be injected and trapped into the second charge trap layer 152 in the second charge trap region 132 due to an electric field created by the negative program voltage −Vpp applied to the word line WL and the first negative bit line voltage −Vpbl applied to the bit line BL. As a result, the absolute value of the threshold voltage of the second charge trap transistor 320 may increase such that the second charge trap transistor 320 has a programmed state. The N-type well region NW may be grounded while the first and second program operations are performed.

To perform an erasure operation, a positive erasure voltage +Vee may be applied to the word line WL, and a second negative bit line voltage −Vebl and a second negative source line voltage −Vesl may be applied to the bit line BL and the source line SL, respectively. In addition, a negative well voltage −Venw may be applied to the N-type well region NW. In some embodiments, the second negative bit line voltage −Vebl, the second negative source line voltage −Vesl and the negative well voltage −Venw may have substantially the same level. Under the above bias condition for the erasure operation, the holes trapped in the first charge trap layer 151 of the first charge trap region 131 and the second charge trap layer 152 of the second charge trap region 132 may be removed. As a result, absolute values of the threshold voltages of the first and second charge trap transistors 310 and 320 may be lowered such that the first and second charge trap transistors 310 and 320 have an erased state.

To perform a first read operation (READ 1) for selectively reading out data stored in the first charge trap transistor 310, a negative read voltage −Vread may be applied to the word line WL and a third negative bit line voltage −Vrbl may be applied to the bit line BL. During the first read operation, the source line SL and the N-type well region NW may be grounded. If the negative read voltage −Vread is applied to the word line WL, the selection transistor 330 in the selection region 133 may be turned on. In addition, a reverse bias may be applied between the N-type well region 112 and the second P-type junction region 116 because the N-type well region 112 is grounded and the third negative bit line voltage −Vrbl is applied to the second P-type junction region 116 through the bit line BL. Thus, a depletion region may be formed in the N-type well region 112 of the second charge trap region 132 and the depletion region may extend to reach a channel region 119 of the selection transistor 333 which is turned on. Accordingly, current flow between the source line SL and the bit line BL may be determined by a threshold voltage of the first charge trap transistor 310. That is, if the absolute value of the threshold voltage of the first charge trap transistor 310 is higher than the absolute value of the negative read voltage −Vread, no current flows between the source line SL and the bit line BL because the first charge trap transistor 310 is turned off. In such a case, the first charge trap transistor 310 may be regarded as being programmed. In contrast, if the absolute value of the threshold voltage of the first charge trap transistor 310 is lower than the absolute value of the negative read voltage −Vread, current may flow between the source line SL and the bit line BL because the first charge trap transistor 310 is turned on. In such a case, the first charge trap transistor 310 may be regarded as being erased.

To perform a second read operation (READ 2) for selectively reading out data stored in the second charge trap transistor 320, a negative read voltage −Vread may be applied to the word line WL and a third negative source line voltage −Vrsl may be applied to the source line SL. During the second read operation, the bit line BL and the N-type well region NW may be grounded. If the negative read voltage −Vread is applied to the word line WL, the selection transistor 330 in the selection region 133 may be turned on. In addition, a reverse bias may be applied between the N-type well region 112 and the first P-type junction region 114 because the N-type well region 112 is grounded and the third negative source line voltage −Vrsl is applied to the first P-type Junction region 114 through the source line SL. Thus, a depletion region may be formed in the N-type well region 112 of the first charge trap region 131 and the depletion region may extend to reach a channel region 119 of the selection transistor 333 which is turned on. Accordingly, current flow between the source line SL and the bit line BL may be determined by the threshold voltage of the second charge trap transistor 320. That is, if the absolute value of the threshold voltage of the second charge trap transistor 320 is higher than the absolute value of the negative read voltage −Vread, no current flows between the source line SL and the bit line BL because the second charge trap transistor 320 is turned off. In such a case, the second charge trap transistor 320 may be regarded as being programmed. In contrast, if the absolute value of the threshold voltage of the second charge trap transistor 320 is lower than the absolute value of the negative read voltage −Vread, current may flow between the source line SL and the bit line BL because the second charge trap transistor 320 is turned on. In such a case, the second charge trap transistor 320 may be regarded as being erased.

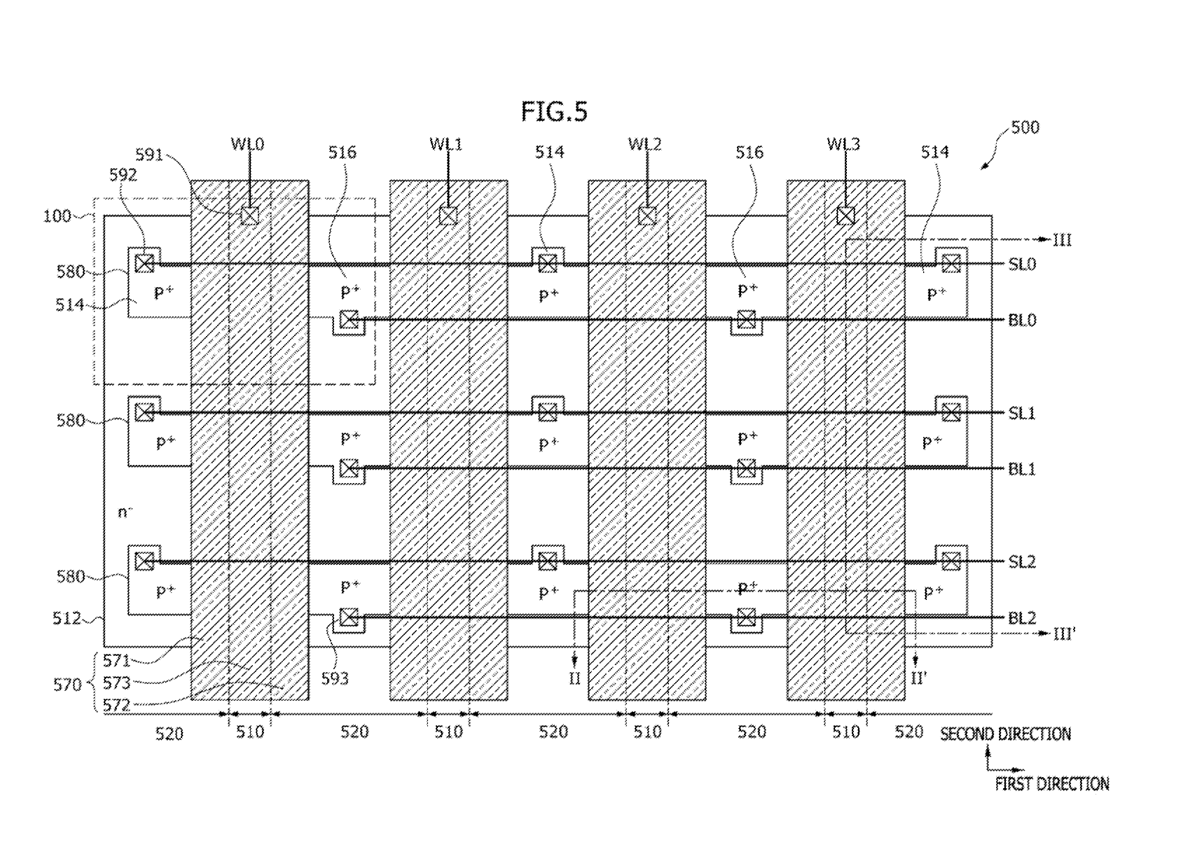

FIG. 5 is a layout diagram illustrating a cell array employing the unit cell shown in FIG. 1. Referring to FIG. 5, a cell array 500 of a nonvolatile memory device according to an embodiment of the inventive concept may include a plurality of selection regions 510 arrayed in a first direction and a plurality of charge trap regions 520 disposed at both sides of each of the selection regions 510. Selection transistors may be disposed in the selection regions 510, and first and second charge trap transistors may be disposed in the charge trap regions 520. The cell array 500 may include a plurality of unit cells 100 which are arrayed in rows parallel with the first direction and in columns parallel with a second direction intersecting the first direction. That is, the plurality of unit cells 100 may be arrayed in a matrix form. Each of the plurality of unit cells 100 may have the same configuration as the unit cell 100 described with reference to FIGS. 1, 2, 3 and 4.

More specifically, a plurality of active regions 580 defined by an isolation layer (not shown) may be disposed to have stripe shapes extending in the first direction. The active regions 580 may be arrayed in the second direction to be spaced apart from each other. All of the active regions 580 may be disposed in an N-type well region 512. A plurality of conductive layers 570 may be disposed to intersect the active regions 580 and to extend in the second direction. That is, the conductive layers 570 may be disposed to have stripe shapes parallel with the second direction and may be arrayed in the first direction to be spaced apart from each other. Each of the conductive layers 570 may include a first conductive layer 571, a second conductive layer 572, and a third conductive layer 573 between the first and second conductive layers 571 and 572. The first, second and third conductive layers 571, 572 and 573 constituting each conductive layer 570 may be a single unified layer. Word line contacts 591 may be disposed on first respective ends of the conductive layers 570, and the conductive layers 570 may be electrically connected to respective word lines WL0, WL1, WL2 and WL3 through the word line contacts 591.

A first P-type junction region 514 and a second P-type junction region 516 may be alternately disposed along the first direction in portions of each active region 580, which are uncovered with the conductive layers 570. First junction region contacts 592 may be disposed on the first P-type junction regions 514, respectively. The first junction region contacts 592 disposed on one active region 580 may be electrically connected to one source line SL0, SL1 or SL2. Second junction region contacts 593 may be disposed on the second P-type junction regions 516, respectively. The second junction region contacts 593 disposed on one active region 580 may be electrically connected to one bit line BL0, BL1 or BL2.

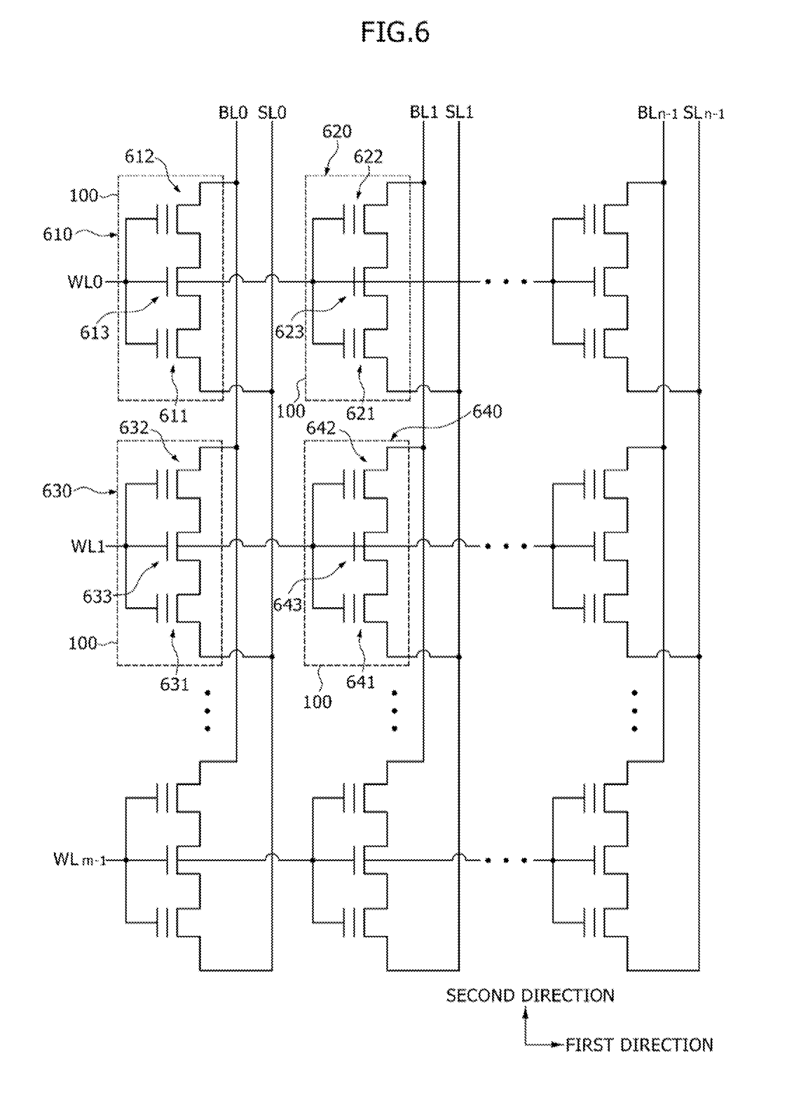

FIG. 6 is an equivalent circuit diagram corresponding to the cell array shown in FIG. 5. Referring to FIG. 6, the unit cells 100 may be arrayed along the first and second directions to have an ‘m×n’ matrix form. Each of the unit cells 100 may include a first charge trap transistor 611, 621, 631 or 641 having an end connected to one source line, a second charge trap transistor 612, 622, 632, or 642 having an end connected to one bit line, and a selection transistor 613, 623, 633, or 643 coupled between the first and second charge trap transistors 611 and 612, 621 and 622, 631 and 632, or 641 and 642. Specifically, the cell array 500 may include m-number of word lines WL0, WL1, . . . , and WLm-1, n-number of source lines SL0, SL1, . . . , and SLn-1, and n-number of bit lines BL0, BL1, . . . , and BLn-1. Each of the word lines WL0, WL1, . . . , and WLm-1 may be electrically connected to n-number of unit cells 100 which are arrayed in the first direction. Each of the source lines SL0, SL1, . . . , and SLn-1 may be electrically connected to m-number of unit cells 100 which are arrayed in the second direction. Similarly, each of the bit lines BL0, BL1, . . . , and BLn-1 may also be electrically connected to the m-number of unit cells 100 which are arrayed in the second direction. In FIG. 6, when the unit cell 100 denoted by a reference numeral “610” corresponds to a selected unit cell, the unit cell 100 denoted by a reference numeral “620” corresponds to a non-selected unit cell that shares the word line WL0 with the selected unit cell 610. The unit cell 100 denoted by a reference numeral “630” corresponds to a non-selected unit cell that shares the source line SL0 and the bit line BL0 with the selected unit cell 610, and the unit cell 100 denoted by a reference numeral “640” corresponds to a non-selected unit cell that does not share any word lines/source lines/bit lines with the selected unit cell 610.

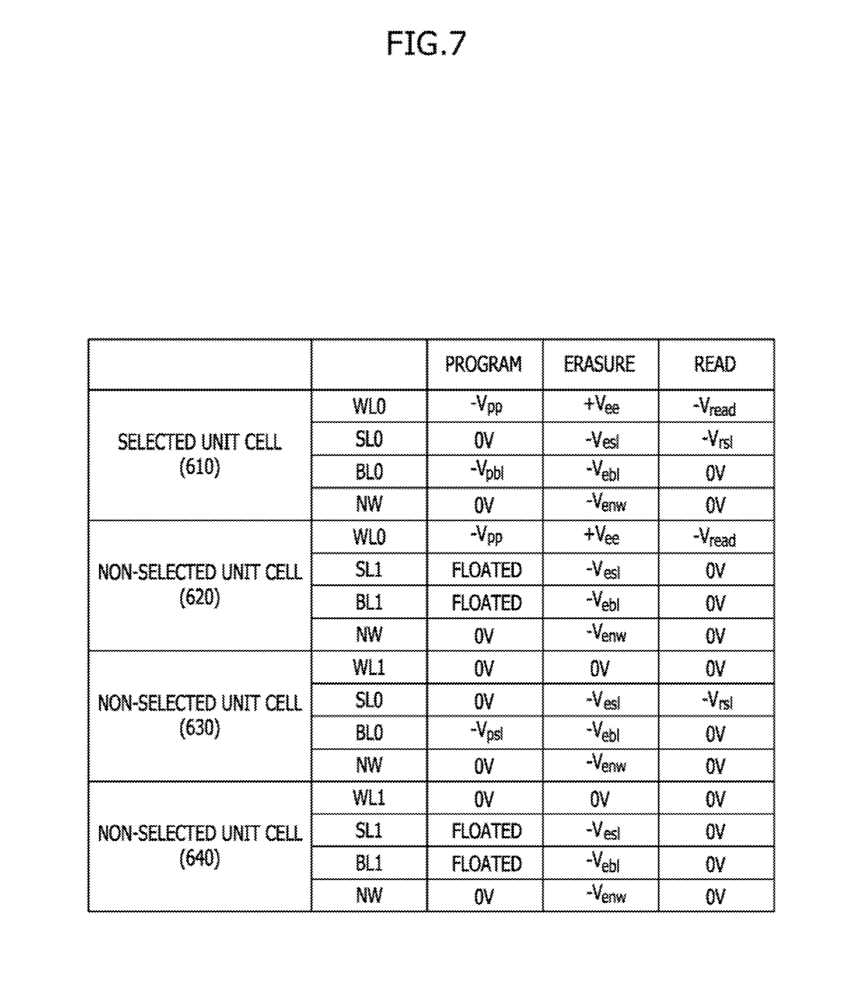

FIG. 7 is a table illustrating bias conditions for operations of the cell array shown in FIG. 6. Referring to FIGS. 6 and 7, in order to perform a program operation for selectively programming the second charge trap transistor 612 (directly connected to the bit line BL0) of the selected unit cell 610, a negative program voltage −Vpp may be applied to the word line WL0 connected to the selected unit cell 610 and a ground voltage may be applied to the remaining word lines WL1, . . . and WLm-1. In addition, a ground voltage may be applied to the source line SL0 connected to the selected unit cell 610 and a first negative bit line voltage −Vpbl may be applied to the bit line BL0 connected to the selected unit cell 610. Moreover, the remaining source lines SL1, . . . and SLn-1 and the remaining bit lines BL1, . . . and BLn-1 may be floated, and the N-type well region 512(NW) may be grounded. Under the aforementioned bias condition, the second charge trap transistor 612 of the selected unit cell 610 may be selectively programmed by a band to band tunneling (BTBT) hot hole injection mechanism.

Since the word line WL1 connected to the unit cells 630 and 640 is grounded, the unit cells 630 and 640 may be unselected regardless of the voltage applied to the source lines SL0 and SL1 and the bit lines BL0 and BL1. Thus, no charge trap transistors of the unit cells 630 and 640 may be programmed. Meanwhile, the negative program voltage −Vpp may also be applied to the word line WL0 connected to the non-selected unit cell 620. Nevertheless, because the source line SL1 and the bit line BL1 connected to the non-selected unit cell 620 are floated, no channel hot holes may be generated in the non-selected unit cell 620. Thus, no charge trap transistors of the non-selected unit cell 620 may be programmed. This embodiment corresponds to an example for selectively programming the second charge trap transistor 612 of the selected unit cell 610, as described above. However, if a voltage corresponding to the first negative bit line voltage −Vpbl is applied to the source line SL0 and the bit line BL0 is grounded, the first charge trap transistor 611 of the selected unit cell 610 may be selectively programmed.

To perform an erasure operation, a positive erasure voltage +Vee may be applied to the word line WL0 connected to the selected unit cell 610 and the remaining word lines WL1, . . . and WLm-1 may be grounded. In addition, a first negative source line voltage −Vesl may be applied to all of the source lines SL0, SL1, . . . and SLn-1 and a second negative bit line voltage −Vebl may be applied to all of the bit lines BL0, BL1, . . . and BLn-1. Moreover, a negative well voltage −Venw may be applied to the N-type well region NW. Under the above bias conditions for the erasure operation, both the first and second charge trap transistors 611 and 612 of the selected unit cell 610 may be erased by a Folwer-Nordheim (F-N) tunneling mechanism. In addition, the first and second charge trap transistors 621 and 622 of the unit cell 620 sharing the word line WL0 with the unit cell 610 may also be erased by an F-N tunneling mechanism. Moreover, the first and second charge trap transistors of the remaining unit cells connected to the word line WL0 may also be erased by an F-N tunneling mechanism. That is, the first and second charge trap transistors of all of the unit cells 100 sharing a selected word line with each other may be erased in a lump during the erasure operation. Since the unit cells 630 and 640 connected to the word line WL1 to which a ground voltage is applied are unselected, no charge trap transistors of the unit cells 630 and 640 may be erased regardless of the voltages applied to the source lines SL0 and SL1 and the bit lines BL0 and BL1.

To perform a read operation for selectively reading out data stored in the second charge trap transistor 612 of the selected unit cell 610, a negative read voltage −Vread may be applied to the word line WL0 connected to the selected unit cell 610 and a ground voltage may be applied to the remaining word lines WL1, . . . and WLm-1. In addition, a second negative source line voltage −Vrsl may be applied to the source line SL0 connected to the selected unit cell 610, and a ground voltage may be applied to the bit line BL0 connected to the selected unit cell 610. Moreover, the remaining source lines SL1, . . . and SLn-1 and the remaining bit lines BL1, . . . and BLn-1 may be grounded, and the N-type well region 512(NW) may also be grounded. Under the above bias conditions for selectively reading out data stored in the selected unit cell 610, the selection transistors 633 and 643 of the unit cells 630 and 640 connected to the grounded word line WL1 may be turned off. Thus, the unit cells 630 and 640 may be unselected regardless of the voltages applied to the source lines SL0 and SL1 and the bit lines BL0 and BL1. Meanwhile, the word line WL0 to which the negative read voltage −Vread is applied may be connected to the non-selected unit cell 620. Nevertheless, because both the source line SL1 and the bit line BL1 connected to the non-selected unit cell 620 are grounded, no current flows through the non-selected unit cell 620. As a result, only the data stored in the second charge trap transistor 612 of the selected unit cell 610 may be selectively read out. This embodiment corresponds to an example for selectively reading out the data stored in the second charge trap transistor 612 of the selected unit cell 610, as described above. However, if a voltage corresponding to the second negative source line voltage −Vrsl is applied to the bit line BL0 and the source line SL0 is grounded, the data stored in the first charge trap transistor 611 of the selected unit cell 610 may be selectively read out.

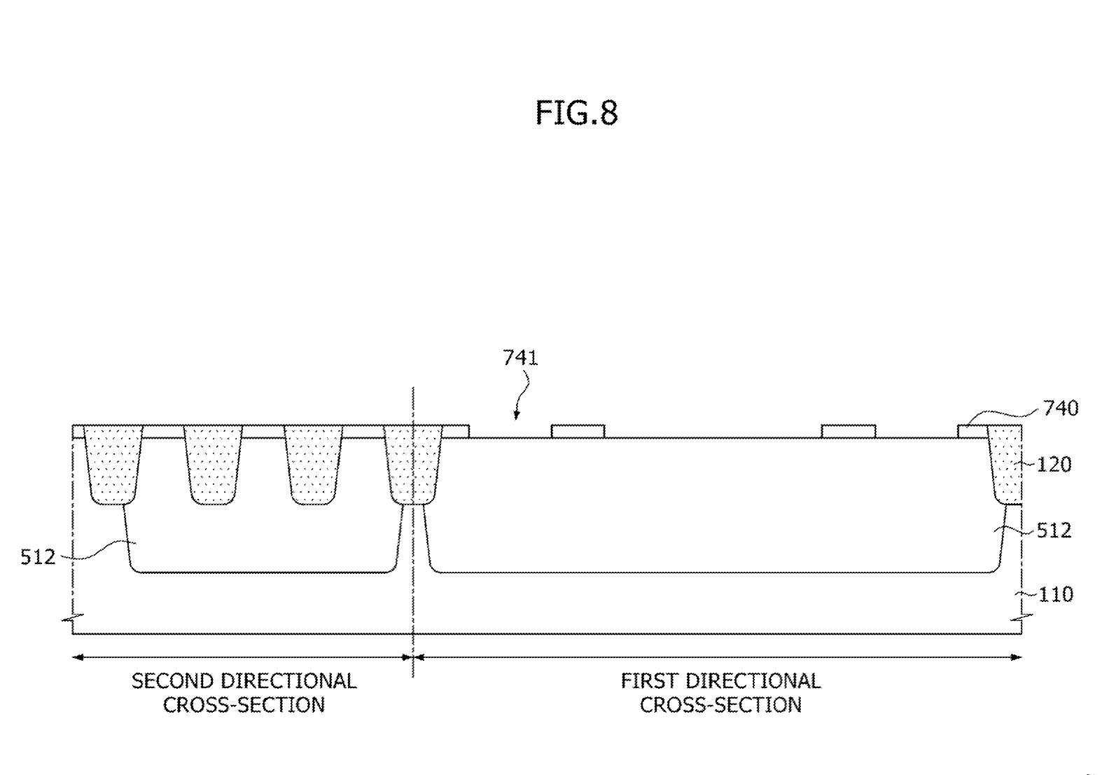

FIGS. 8 to 13 are cross-sectional views illustrating a method of fabricating a nonvolatile memory device according to an embodiment of the inventive concept. In each of FIGS. 8 to 13, a right portion corresponds to a first directional cross-section of FIG. 5 and a left portion corresponds to a second directional cross-section of FIG. 5. That is, the right portions of FIGS. 8 to 13 are cross-sectional views taken along a line II-II′ of FIG. 5 and the left portions of FIGS. 8 to 13 are cross-sectional views taken along a line III-III′ of FIG. 5. As illustrated in FIG. 8, an isolation layer 120 may be formed in a substrate 110, such as a silicon substrate, to define active regions. The isolation layer 120 may be formed using a trench isolation process. In some embodiments, a well region 512 may be formed in the substrate 110 using a well formation ion implantation process before the isolation layer 120 is formed. The well region 512 may be formed by implanting N-type impurities into the substrate 110. In some embodiments, the well region 512 may be formed using a well formation ion implantation process after the isolation layer 120 is formed. First tunneling layers 740 may be formed on portions of the active regions defined by the isolation layer 120. The active regions may be located in the well region 512. The first tunneling layers 740 may be separated from each other by openings 741 that expose the well region 512. In some embodiments, the first tunneling layers 740 may be formed of an oxide layer. To form the first tunneling layers 740, a first tunneling material may be formed on an entire surface of the substrate 110 including the isolation layer 120 and the well region 512. Subsequently, a mask pattern, for example, a photoresist pattern, may be formed on the first tunneling material to expose portions of the first tunneling material. The first tunneling material may then be etched using the mask pattern as an etch mask to remove the exposed portions of the first tunneling material. As a result, portions of the well regions 512 may be exposed. Thereafter, the mask pattern may be removed.

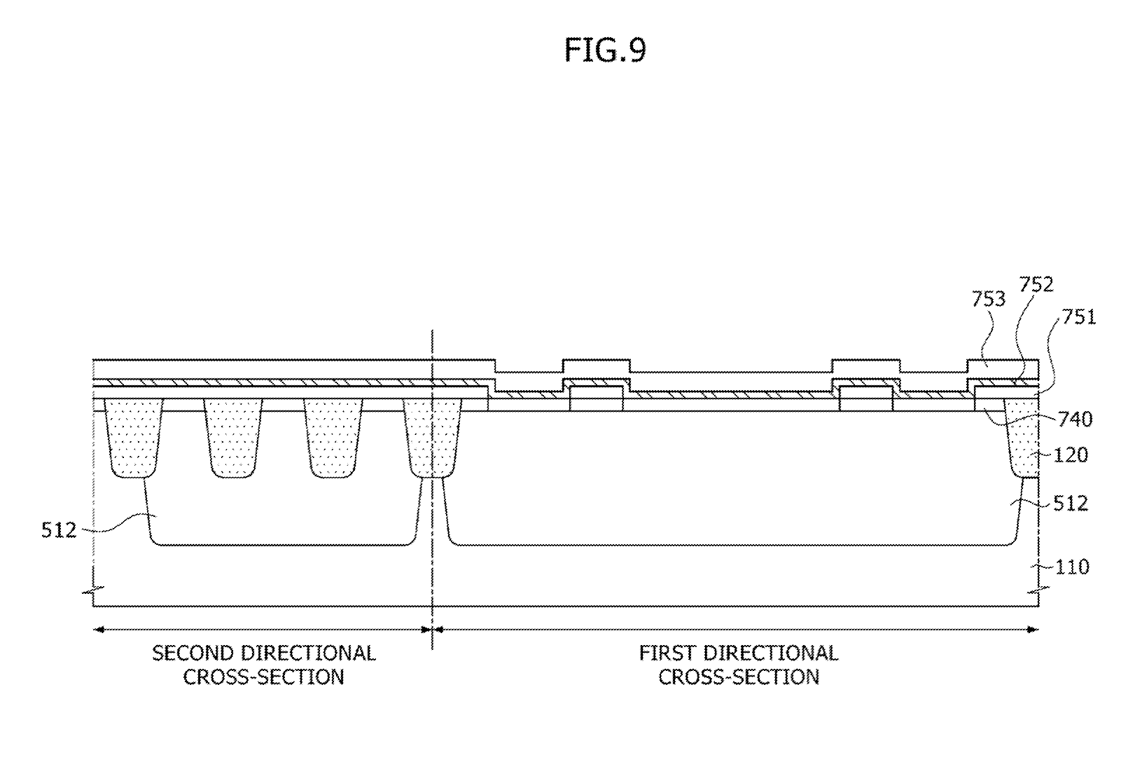

As illustrated in FIG. 9, a second tunneling layer 751, a charge trap layer 752 and an insulation layer 753 may be sequentially formed on the first tunneling layers 740 and the exposed portions of the well region 512. The second tunneling layer 751 may be formed of an oxide layer. The charge trap layer 752 may be formed of a nitride layer. The insulation layer 753 may be formed of an oxide layer. In the first directional cross-section of FIG. 9, the first tunneling layer 740, the second tunneling layer 751, the charge trap layer 752 and the Insulation layer 753 may be sequentially stacked on each of the first regions of the well region 512, and the second tunneling layer 751, the charge trap layer 752 and the insulation layer 753 may be sequentially stacked on each of second regions of the well region 512.

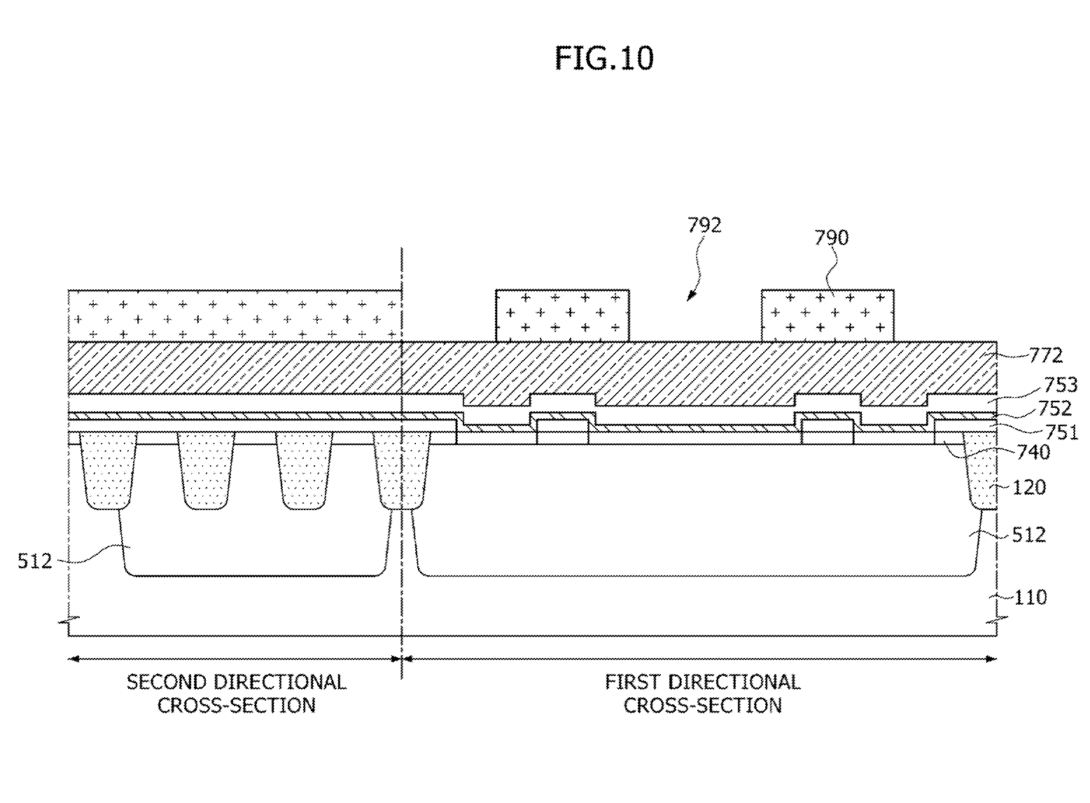

As illustrated in FIG. 10, a conductive layer 772 may be formed on the entire surface of the insulation layer 753. The conductive layer 772 may be formed of a polysilicon layer doped with impurity ions. A mask pattern 790 having openings 792 exposing portions of the conductive layer 772 may be formed on the conductive layer 772. The mask pattern 790 may be formed of a photoresist layer. The mask pattern 790 may overlap with the conductive layer 772 formed over the first tunneling layers 740 and their both sides.

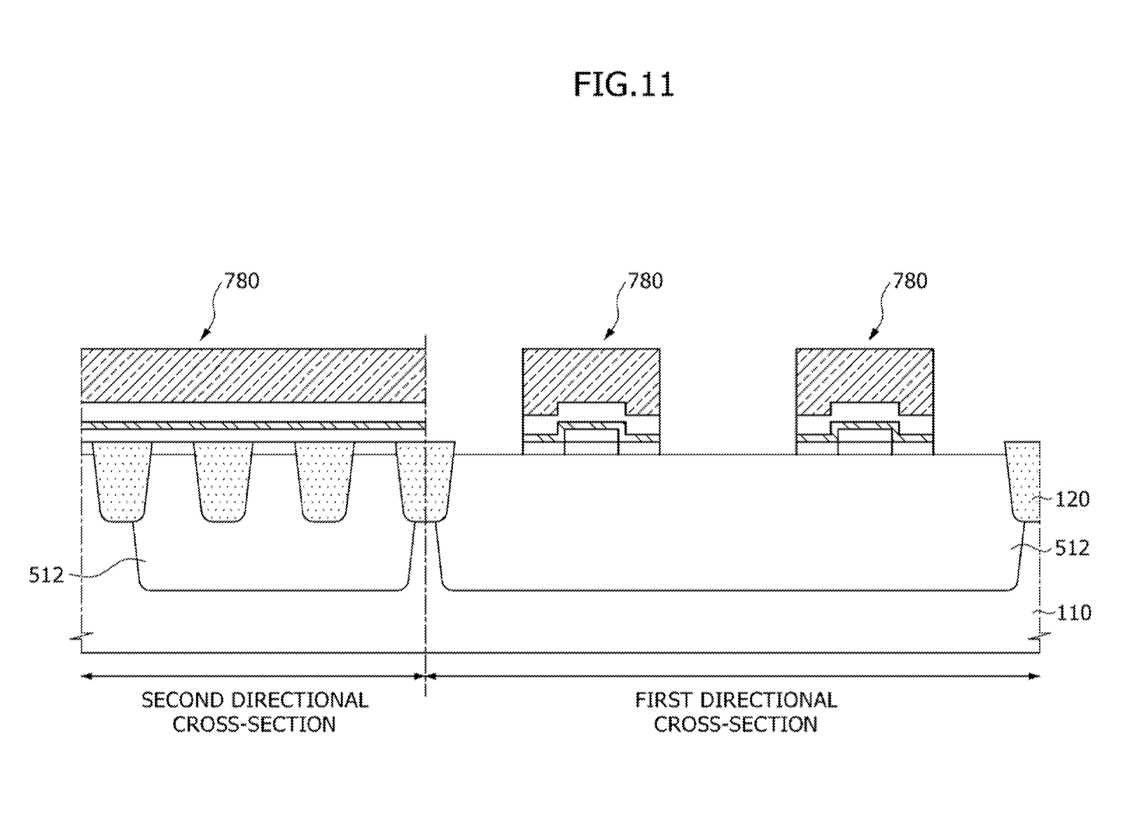

As illustrated in FIG. 11, the conductive layer 772, the insulation layer 753, the charge trap layer 752 and the second tunneling layer 751 may be etched using the mask pattern 790 as an etch mask to form gate structures 780 on the well region 512. Each of the gate structures 780 may be formed to have the same structure as the gate structure 180 described with reference to FIG. 2. The mask pattern 790 may then be removed.

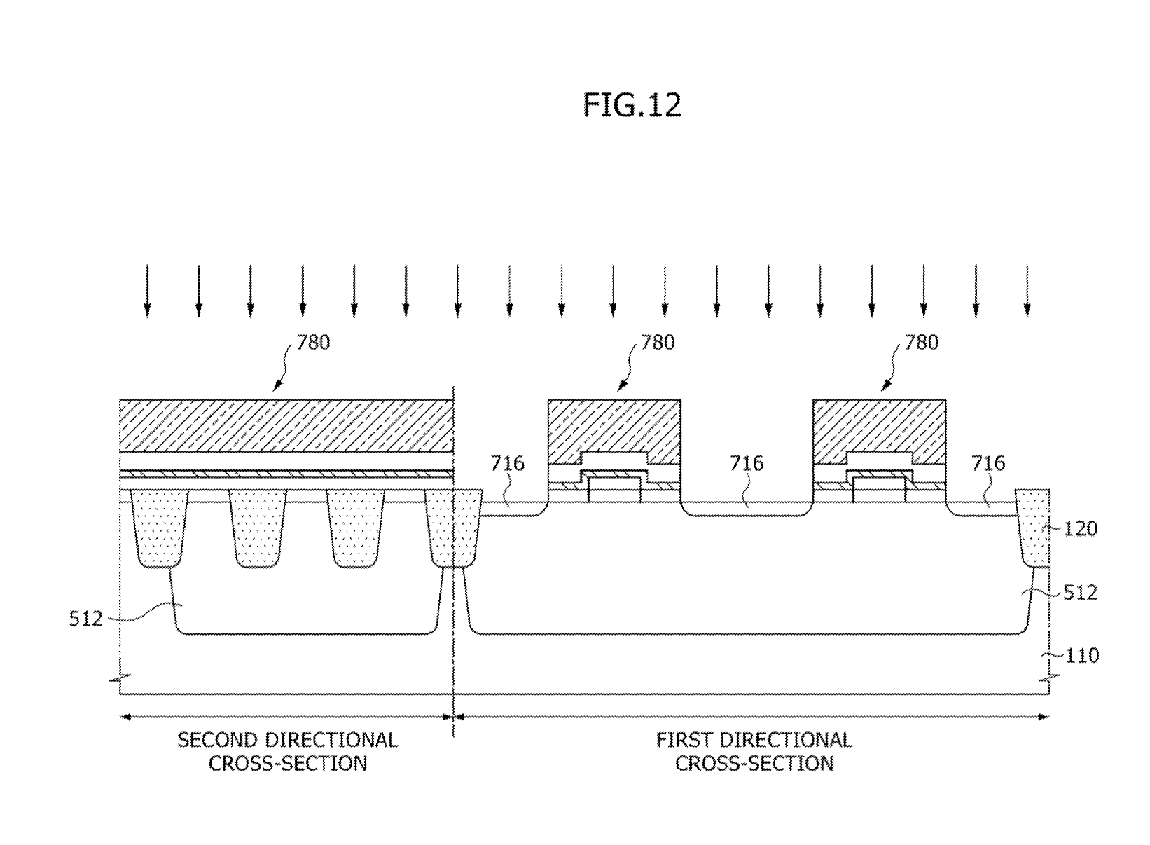

Referring to FIG. 12, source/drain extension regions 716 may be formed in the well region 512 using an ion implantation process, as denoted by arrows. The ion implantation process for forming the source/drain extension regions 716 may be performed using the gate structures 780 and the isolation layer 120 as implantation masks. In some embodiments, the source/drain extension regions 716 may be formed by implanting P-type impurities into the well region 512. That is, the source/drain extension regions 716 may be doped with P-type impurities.

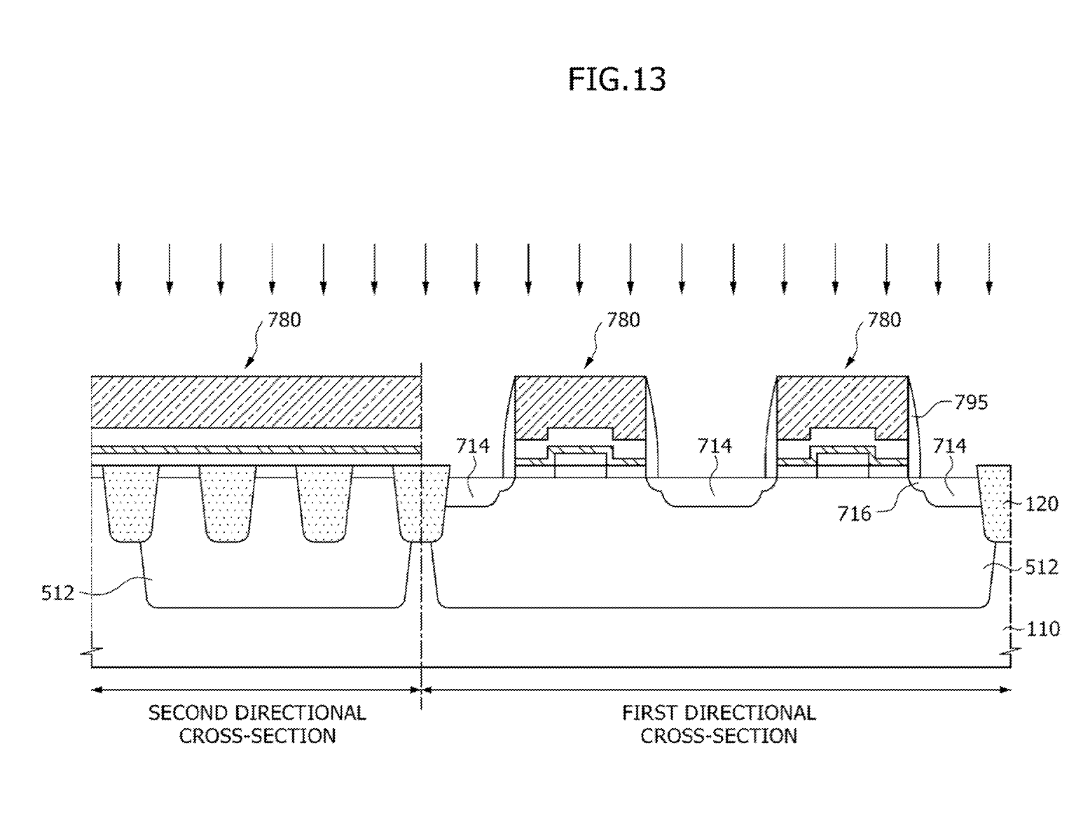

Referring to FIG. 13, gate spacers 795 may be formed on sidewalls of the gate structures 780. Deep source/drain regions 714 may be formed in the well region 512 using an ion implantation process, as denoted by arrows. The ion implantation process for forming the deep source/drain regions 714 may be performed using the gate structures 780 and the gate spacers 795 as ion implantation masks. In some embodiments, the deep source/drain regions 714 may be formed by implanting P-type impurities into the well region 512. That is, the deep source/drain regions 714 may be doped with P-type impurities. The source/drain extension regions 716 and the deep source/drain regions 714 may constitute lightly doped drain (LDD) structures. Although not shown in the drawings, a metal silicide layer may be additionally formed on the deep source/drain regions 714.

The embodiments of the inventive concept have been disclosed above for illustrative purposes. Those skilled in the art will appreciate that various modifications, additions and substitutions are possible, without departing from the scope and spirit of the inventive concept as disclosed in the accompanying claims.

What is claimed is:

1. A nonvolatile memory device comprising:
a substrate having a first charge trap region, a second charge trap region, and a selection region between the first and second charge trap regions, wherein the first charge trap region, the selection region and the second charge trap region are arrayed in one direction;
a well region having a first conductivity type and disposed in the substrate, wherein a surface of the well region is exposed;
a source region and a drain region disposed in the well region to be separated from each other by a channel region, wherein the source region and the drain region have a second conductivity type different from the first conductivity type; and
a gate structure disposed on the channel region,
wherein the gate structure includes: a first tunneling layer, a first charge trap layer, a first blocking layer and a first conductive layer, stacked in the first charge trap region; a second tunneling layer, a second charge trap layer, a second blocking layer and a second conductive layer stacked in the second charge trap region; and a first insulation layer, a second insulation layer, a third insulation layer and a third conductive layer stacked in the selection region.

2. The nonvolatile memory device of claim 1,
wherein the gate structure is included in first and second charge trap transistors formed in first and second charge trap regions, and a selection transistor formed in the selection region;
wherein the first and second conductive layers correspond to a first control gate layer of the first charge trap transistor and a second control gate layer of the second charge trap transistor, respectively; and
wherein the third conductive layer corresponds to a gate electrode layer of the selection transistor.

3. The nonvolatile memory device of claim 1, wherein the first insulation layer includes a first lower insulation layer and a first upper insulation layer.

4. The nonvolatile memory device of claim 3, wherein the first tunneling layer, the second tunneling layer and the first upper insulation layer are comprised of the same material layer.

5. The nonvolatile memory device of claim 4, wherein the first tunneling layer, the second tunneling layer and the first upper insulation layer constitute a single oxide layer.

6. The nonvolatile memory device of claim 3, wherein the first lower insulation layer, the first tunneling layer and the second tunneling layer have substantially the same thickness.

7. The nonvolatile memory device of claim 3, wherein the first charge trap layer, the second charge trap layer and the second insulation layer are arrayed in the one direction to constitute a single layer.

8. The nonvolatile memory device of claim 7,
wherein the first charge trap layer in the first charge trap region and the second insulation layer in the selection region have a level difference therebetween, and the second charge trap layer in the second charge trap region and the second insulation layer in the selection region have a level difference therebetween; and
wherein the level differences are substantially equal to a thickness of the first upper insulation layer.

9. The nonvolatile memory device of claim 7, wherein the first charge trap layer, the second charge trap layer and the second insulation layer are the same material layer.

10. The nonvolatile memory device of claim 9, wherein the first charge trap layer, the second charge trap layer and the second insulation layer constitute a single nitride layer.

11. The nonvolatile memory device of claim 3, wherein the first blocking layer, the second blocking layer and the third insulation layer are arrayed in the one direction to constitute a single layer.

12. The nonvolatile memory device of claim 11,
wherein the first blocking layer in the first charge trap region and the third insulation layer in the selection region have a level difference therebetween, and the second blocking layer in the second charge trap region and the third insulation layer in the selection region have a level difference therebetween; and
wherein the level differences are substantially equal to a thickness of the first upper insulation layer.

13. The nonvolatile memory device of claim 3, wherein the first conductive layer, the second conductive layer and the third conductive layer are arrayed in the one direction to constitute a single layer.

14. The nonvolatile memory device of claim 13,
wherein the first conductive layer in the first charge trap region and the third conductive layer in the selection region have a level difference between bottom surfaces thereof, and the second conductive layer in the second charge trap region and the third conductive layer in the selection region have a level difference between bottom surfaces thereof; and
wherein the level differences are substantially equal to a thickness of the first upper insulation layer.

15. The nonvolatile memory device of claim 13, wherein the first conductive layer, the second conductive layer and the third conductive layer are the same material layer.

16. The nonvolatile memory device of claim 15, wherein the first conductive layer, the second conductive layer and the third conductive layer constitute a single polysilicon layer.

17. The nonvolatile memory device of claim 1, wherein the first conductivity type is an N-type and the second conductivity type is a P-type.

18. A method of fabricating a nonvolatile memory device, the method comprising:
forming a well region in a substrate, wherein a surface of the well region is exposed;
forming a first tunneling material on the well region;
removing portions of the first tunneling material to form first tunneling layers exposing portions of the well region;
sequentially forming a second tunneling layer, a charge trap layer and an insulation layer on the first tunneling layers and exposed portions of the well region;
forming a conductive layer on the insulation layer;
patterning the conductive layer, the insulation layer, the charge trap layer and the second tunneling layer to form gate structures exposing portions of the well region; and
forming source/drain regions in exposed portions of the well region.

19. A nonvolatile memory device comprising:
a substrate having a first charge trap region, a selection region, and a second charge trap region arrayed in one direction;
a insulating layer formed on the substrate in the selection region;
a tunneling layer, a charge trap layer, and an blocking layer stacked on the insulating layer in the selection region and on the substrate in the first and second charge trap regions; and
a conductive layer formed on the blocking layer,
wherein the tunneling layer, the charge trap layer, and the blocking layer have a level difference between the first charge trap region and the selection region and between the selection region and the second charge trap region.

20. The nonvolatile memory device of claim 19, wherein the level difference is substantially equal to a thickness of the tunneling layer.
